(19) United States
(12) Patent Application Publication
(10) Pub. No.: US 2013/0148310 A1
(43) Pub. Date: Jun. 13, 2013

(54) PRINTED CIRCUIT BOARD HAVING WIRE PATTERN

(71) Applicant: SAMSUNG ELECTRONICS CO., LTD., Suwon-si (KR)

(72) Inventor: Yong-Kwan LEE, Hwaseong-si (KR)

(73) Assignee: SAMSUNG ELECTRONICS CO., LTD., Suwon-si (KR)

(21) Appl. No.: 13/706,645

(22) Filed: Dec. 6, 2012

(30) Foreign Application Priority Data
Dec. 8, 2011 (KR) 10-2011-0131108

(51) Int. Cl. H05K 1/02; H01L 25/00

(52) U.S. Cl. CPC H05K 1/0298; H05K 1/02; H01L 25/00
USPC 361/728; 174/250; 174/262

(57) ABSTRACT

A printed circuit board (PCB) includes a wire pattern having first and second surfaces facing in opposite directions from each other, the wire pattern including a first region having a first thickness and a second region having a second thickness greater than the first thickness; a core insulation layer on the second surface in the first region, the core insulation layer having a third surface adjacent to the second surface in the first region and a fourth surface facing in an opposite direction from the third surface, the fourth surface being connected to the second surface; and a first protection layer covering a portion of the fourth surface of the core insulation layer and a portion of the second surface in the second region.

### CROSS-REFERENCE TO RELATED APPLICATION

Korean Patent Application No. 10-2011-0131108 filed on Dec. 8, 2011, in the Korean Intellectual Property Office, and entitled: “Printed Circuit Board Having Wire Pattern,” is incorporated by reference herein in its entirety.

### BACKGROUND

1. Field

Embodiments relate to a printed circuit board (PCB) including a wire pattern.

2. Description of the Related Art

A semiconductor package can be fabricated using semiconductor chips, a printed circuit board (PCB) on which semiconductor chips are mounted, and a sealing member for sealing the semiconductor chips.

### SUMMARY

Embodiments are directed to a printed circuit board (PCB) including a wire pattern having first and second surfaces facing in opposite directions from each other, the wire pattern including a first region having a first thickness and a second region having a second thickness greater than the first thickness, a core insulation layer on the second surface in the first region, the core insulation layer having a third surface adjacent to the second surface in the first region and a fourth surface facing in an opposite direction from the third surface, the fourth surface being connected to the second surface, and a first protection layer covering a portion of the fourth surface of the core insulation layer and a portion of the second surface in the second region.

The first protection layer may include an opening exposing another portion of the second surface in the second region. A width of the opening may be smaller than a width of the second region.

The PCB may further include a first external connection terminal on the second surface in the second region, the first external connection terminal extending through the opening. The PCB may further include a second external connection terminal on the first surface in the first region. The PCB may further include a second protection layer on the first surface of the wire pattern.

The wire pattern may further include a third region having a third thickness greater than the first thickness and not greater than the second thickness. The third thickness may be two or more times greater than the first thickness. The first protection layer may cover the second surface in the third region.

The second region may be a region to which an external voltage is applied or a region that is grounded. The first region of the wire pattern may not be on the fourth surface of the core insulation layer.

Embodiments are also directed to a printed circuit board (PCB) including a wire pattern having first and second surfaces facing in opposite directions from each other, the wire pattern including a first region having a first thickness, a second region having a second thickness greater than the first thickness, and third region having a third thickness greater than the first thickness and not greater than the second thickness, a core insulation layer on the second surface of the wire pattern in the first region, the core insulation layer having a third surface adjacent to the second surface of the wire pattern in the first region and a fourth surface facing in an opposite direction from the third surface, the fourth surface being connected to the second surface of the wire pattern, and a first external connection terminal formed on the second surface of the wire pattern in the second region but not in the third region.

The PCB may further include a first protection layer covering at least a portion of the second surface of the wire pattern in the third region. The PCB may further include a second protection layer on the first surface of the wire pattern.

The PCB may further include a first protection layer covering a portion of the fourth surface of the core insulation layer and a portion of the second surface of the wire pattern in the second region. The first protection layer may include an opening exposing another portion of the second surface of the wire pattern in the second region. A width of the opening is smaller than that of the second region. The first external connection terminal may be formed on the second surface of the wire pattern in second region through the opening.

The core insulation layer may also be on the second surface of the wire pattern in the third region.

Embodiments are also directed to a semiconductor package including a semiconductor device, a printed circuit board (PCB) on which the semiconductor device is mounted, and a sealing member sealing the semiconductor device. The printed circuit board includes a wire pattern having first and second surfaces facing in opposite directions from each other, the wire pattern including a first region having a first thickness and a second region having a second thickness greater than the first thickness, the second surface in the second region being stepped from the second surface in the first region. The printed circuit board further includes a core insulation layer on the second surface in the first region, the core insulation layer having a third surface contacting the second surface in the first region and a fourth surface facing in an opposite direction from the third surface, the fourth surface being connected to and co-planar with the second surface, a first protection layer covering a portion of the fourth surface, a first external connection terminal on the second surface in the second region, and a second external connection terminal on the first surface, the semiconductor device being mounted on the PCB using the second external connection terminal.

The first protection layer may cover a portion of the second surface in the second region and may include an opening exposing another portion of the second surface in the second region, a width of the opening being smaller than a width of the second region, and the first external connection terminal extending through the opening.

The wire pattern may further include a third region having a third thickness greater than the first thickness and not greater than the second thickness. The first protection layer may cover at least a portion of the second surface in the third region.

The third thickness of the second surface may be less than the second thickness of the second surface. The core insulation layer may be on the second surface in the third region.

### BRIEF DESCRIPTION OF THE DRAWINGS

Features will become apparent to those of skill in the art by describing in detail exemplary embodiments with reference to the attached drawings in which:

FIG. 1 illustrates a cross-sectional view of a semiconductor package including a printed circuit board according to an embodiment;

FIG. 2 illustrates a cross-sectional view of a printed circuit board according to the embodiment of FIG. 1;

FIG. 3 illustrates a cross-sectional view of a semiconductor package including a printed circuit board according to another embodiment;

FIG. 4 illustrates a cross-sectional view of a semiconductor package including a printed circuit board according to another embodiment;

FIG. 5 illustrates a cross-sectional view of a semiconductor package including a printed circuit board according to another embodiment;

FIG. 6 illustrates a cross-sectional view of a semiconductor package including a printed circuit board according to another embodiment;

FIG. 7 illustrates a cross-sectional view of a semiconductor package including a printed circuit board according to a another embodiment;

FIGS. 8 to 12 illustrate cross-sectional views of intermediate structures for explaining a manufacturing method of a printed circuit board according to an embodiment;

FIG. 13 illustrates a plan view of a printed circuit board according to an embodiment; and

FIG. 14 illustrates a cross-sectional view of an intermediate structure for explaining a manufacturing method of a printed circuit board according to another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope thereof to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings thereof.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the relevant art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

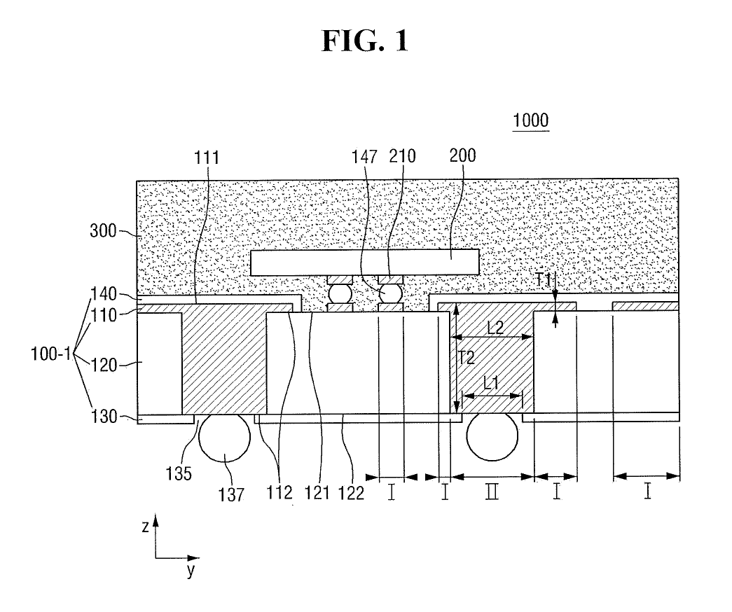

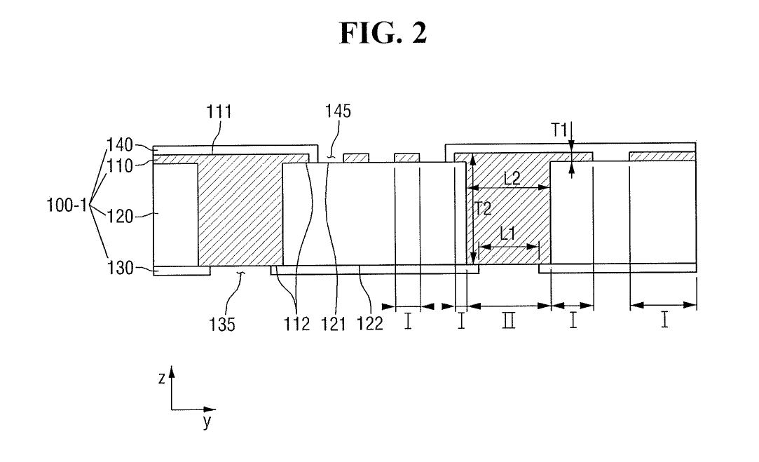

A printed circuit board (PCB) according to an embodiment will be described with reference to FIGS. 1 and 2. Referring to FIG. 1, a semiconductor package 1000 may include a printed circuit board 100-1, a semiconductor chip 200, and a sealing member 300.

The semiconductor chip 200 may be mounted on the PCB 100-1 using a second external connection terminal 147 by a flip chip method. For example, the second external connection terminal 147 may be positioned between a pad 210 of the semiconductor chip 200 and a first region (I) of a wire pattern 110 of the PCB 100-1. The semiconductor chip 200 may be electrically connected to the PCB 100-1 through the second external connection terminal 147. The semiconductor chip 200 may be, for example, a memory chip such as DRAM or flash memory, or a logic chip of a controller.

The second external connection terminal 147 may be a conductive ball or a solder ball, as examples. In other implementations, the second external connection terminal 147 may be one selected from the group of a conductive bump, a conductive spacer, and a pin grid array (PGA).

The sealing member 300 seals the semiconductor chip 200 attached to the PCB 100-1 by flip chip bonding to protect the semiconductor chip. The sealing member 300 may be a suitable sealing material such as, for example, an epoxy molding compound (EMC).

Referring to FIGS. 1 and 2, the PCB 100-1 may include a wire pattern 110, a core insulation layer 120, and first and second protection layers 130 and 140.

The wire pattern 110 may be a structure having a wire pattern present on one of a third surface 121 and a fourth surface 122 of the core insulation layer 120. For example, the wire pattern 110 may be present on the third surface 121 of the core insulation layer 120 and not present on the fourth surface 122 of the core insulation layer. The wire pattern 110 is to be distinguished from a double-layered wire pattern, which has wire patterns on two opposite surfaces of a core insulation layer. For example, in a case of the wire pattern 110, a first region (I) of the wire pattern 110 is not formed on the fourth surface 122 of the core insulation layer 120.

The wire pattern 110 may have first and second surfaces 111 and 112 facing in opposite directions from each other. In addition, the wire pattern 110 may have a first region (I) and a second region (II). The first region (I) may be defined as a region of the wire pattern 110 having a first thickness (T1) and the second region (II) may be defined as a region of the wire pattern 110 having a second thickness (T2). Here, the second thickness (T2) may be greater than the first thickness (T1). The wire pattern 110 may include, for example, copper (Cu).

The core insulation layer 120 may be formed on the second surface 112 of wire pattern in the first region (I) of the wire pattern 110 and may be present between the first and second protection layers 130 and 140.

The core insulation layer 120 may have third and fourth surfaces 121 and 122 facing in opposite directions from each other. In addition, part of the third surface 121 of the core insulation layer 120 may adjoin the second surface 112 of the first region (I) of the wire pattern 110. Another part of the third surface 121 of the core insulation layer 120 may adjoin the second protection layer 140. The fourth surface 122 of the core insulation layer 120 may adjoin the first protection layer 130.

The fourth surface 122 of the core insulation layer 120 and the second surface 112 of the wire pattern 110 in the second region (II) may be formed to be connected to each other. For example, the fourth surface 122 of the core insulation layer 120 and the second surface 112 of the wire pattern in the second region (II) may be formed to have the same height on the z axis. The second surface 112 and the fourth surface 122 may be co-planar.

The core insulation layer 120 may include an insulating material, such as, for example, a prepreg resin prepared by infiltrating a thermosetting resin into a glass fiber to be made into a semi-hardened state, a thermosetting epoxy resin, a thermoplastic epoxy resin and a filler-containing resin.

The first protection layer 130 may cover part of the fourth surface 122 of the core insulation layer 120 and part of the second surface 112 of the wire pattern 110 in the second region (II). The first protection layer 130 may cover only a part of the second surface 112 of the wire pattern 110 in the second region (II). Accordingly, the first protection layer 130 may include a first opening 135 exposing another part of the second surface 112 of the wire pattern 110 in the second region (II). The first opening 135 may be formed to expose the second surface 112 of the wire pattern 110 in the second region (II). A width L1 of the first opening 135 may be smaller than a width L2 of the second region (II) of the wire pattern 110.

A first external connection terminal 137 may be formed where the second surface 112 of the wire pattern 110 in the second region (II) is exposed through the first opening 135. The first external connection terminal 137 may be a conductive ball or a solder ball, for example.

The second protection layer 140 may be formed on the first surface 111 of the wire pattern 110 and the third surface 121 of the core insulation layer 120. The second protection layer 140 may include a second opening 145. Part of the first surface 111 of the wire pattern 110 and part of the third surface 121 of the core insulation layer 120 may be exposed through the second opening 145.

The first protection layer 130 and the second protection layer 140 may include an insulating material such as solder resist (SR), as an example.

As described above, the PCB 100-1 according to this embodiment may include the first opening 135 formed on the second surface 112 of the wire pattern 110 in the second region (II). In addition, the width L1 of the first opening 135 may be smaller than the width L2 of the second region (II) of the wire pattern 110. The width L2 of the second region (II) of the wire pattern 110 may be greater than the width L1 of the first opening 135.

In order to connect the second region (II) of the wire pattern 110 to the first external connection terminal 137, the second region (II) of the wire pattern 110 may have a second thickness T2 greater than the first thickness T1 of the first region (II). Therefore, the second region (II) of the wire pattern 110 may extend toward the first protection layer 130 (e.g., the z axis direction), compared to the first region (I) of the wire pattern 110.

Even if the width of the second region (II) of the wire pattern 110 is equal to or smaller than the width of the first opening 135, the first external connection terminal 137 may be formed on the second region (II) of the wire pattern 110. In the PCB 100-1 according to this embodiment, the width L2 of the second region (II) of the wire pattern 110 is greater than the width L1 of the first opening 135. The PCB 100-1 according to this embodiment includes the second region (II) of the wire pattern 110, which extends toward the y axis direction. Accordingly, a sufficiently wide area of the second region (II) of the wire pattern 110 may be secured. For example, if an external voltage is applied or grounded through the first external connection terminal 137, a sufficiently wide area of the second region (II) of the wire pattern 110 may be secured, and electrical performance of a semiconductor device using the PCB 100-1 according to this embodiment may be prevented from being degraded.

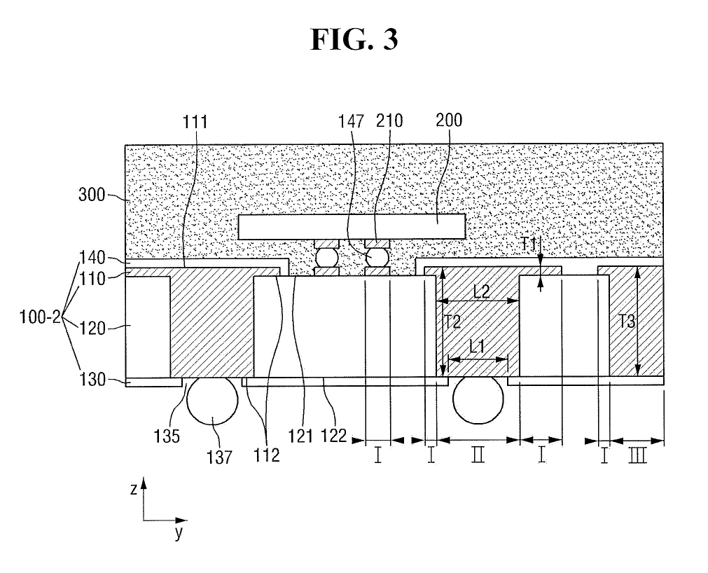

A PCB 100-2 according to another embodiment will be described with reference to FIG. 3. FIG. 3 is a cross-sectional view of a semiconductor package including a printed circuit board according to this embodiment. However, the following description will be focus on differences between the PCBs according to this embodiment and the embodiment described above.

Referring to FIG. 3, the PCB 100-2 according to this embodiment may include a wire pattern 110 further including a third region (III).

The wire pattern 110 may have first and second surfaces 111 and 112 facing in opposite directions from each other and first to third regions (I, II and III). The first region (I) may be defined as a region of the wire pattern 110 having a first thickness (T1), and the second region (II) may be defined as a region of the wire pattern 110 having a second thickness (T2). A first external connection terminal 137 may be formed on the second surface 112 of the wire pattern 110 in the second region (II). The third region (III) may be defined as a region of the wire pattern 110 having a third thickness T3. The first external connection terminal 137 is not formed in the third region (III). The second thickness T2 and the third thickness T3 may be greater than the first thickness T1. The second thickness T2 and the third thickness T3 may be equal to each other.

Although the second thickness T2 of the second region (II) and the third thickness T3 of the third region (III) may be equal to each other, the first external connection terminal 137 is not formed in the third region (III). Accordingly, the second region (II) and the third region (III) may be distinguished from each other.

The second surface 112 of the wire pattern 110 in the second region (I) may be covered by the first protection layer 130. In addition, the fourth surface 122 of the core insulation layer 120 and the second surface 112 of the wire pattern 110 in the third region (III) may be formed to be connected to each other. For example, the fourth surface 122 of the core insulation layer 120 and the second surface 112 of the wire pattern 110 in the third region (III) of the wire pattern 110 may be formed to have the same height on the z axis, but aspects are not limited thereto. The fourth surface 122 of the core insulation layer 120 and the second surface 112 of the wire pattern 110 in the third region (III) may be co-planar.

As described above, the PCB 100-2 according to this embodiment may include the third region (III) of the wire pattern 110 having the third thickness T3. The third thickness T3 of the third region (III) of the wire pattern 110 may be greater than the first thickness T1 of the first region (I) of the wire pattern 110. Accordingly, the third region (III) of the wire pattern 110 may extend toward the first protection layer 130 (e.g., the z axis direction), compared to the first region (I) of the wire pattern 110.

The PCB 100-2 according to this embodiment includes the third region (III) of the wire pattern 110, which extends toward the z axis direction. Accordingly, a sufficiently wide area of the third region (III) of the wire pattern 110 may be secured. For example, in a case where the third region (III) of the wire pattern 110 is a region associated with a voltage circuit or a ground circuit, a sufficiently wide area of the third region (III) of the wire pattern 110 may be secured, and electrical performance of a semiconductor device using the PCB 100-2 according to this embodiment may be prevented from being degraded.

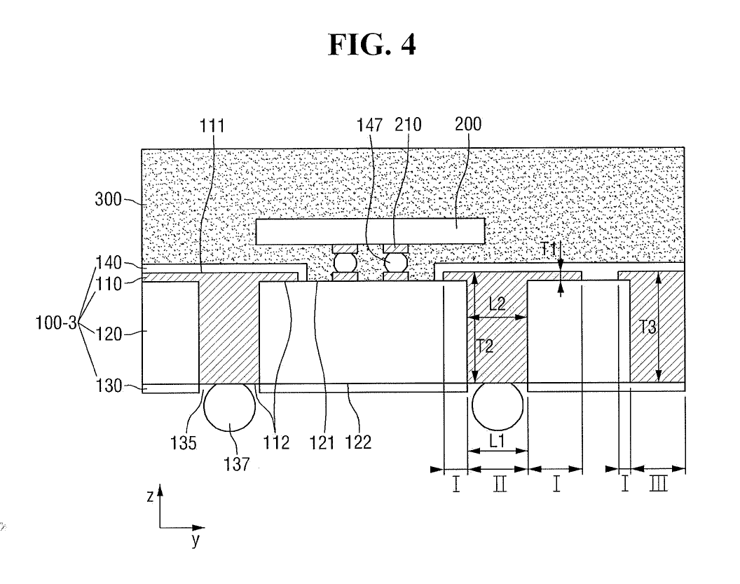

A PCB according to another embodiment will be described with reference to FIG. 4. FIG. 4 is a cross-sectional view of a semiconductor package including a printed circuit board according to the embodiment. The following description will focus on differences between the PCBs according to this embodiment and the embodiment illustrated in FIG. 3.

Referring to FIG. 4, in the PCB 100-3 according to this embodiment, a width L2 of a second region (II) of a wire pattern 110 is not greater than a width L1 of a first opening 135, unlike in the PCB 100-2 according to the embodiment of FIG. 3. The width L2 of the second region (II) of the wire pattern 110 may be equal to or smaller than the width L1 of the first opening 135. FIG. 4 illustrates the example that the width L2 of the second region (II) of the wire pattern 110 may be equal to the width L1 of the first opening 135

The PCB 100-3 according to this embodiment may include the third region (III) of the wire pattern 110, which extends toward the z axis direction. Accordingly, a sufficiently wide area of the third region (III) of the wire pattern 110 may be secured. Therefore, electrical performance of a semiconductor device using the PCB 100-3 according to this embodiment may be prevented from being degraded.

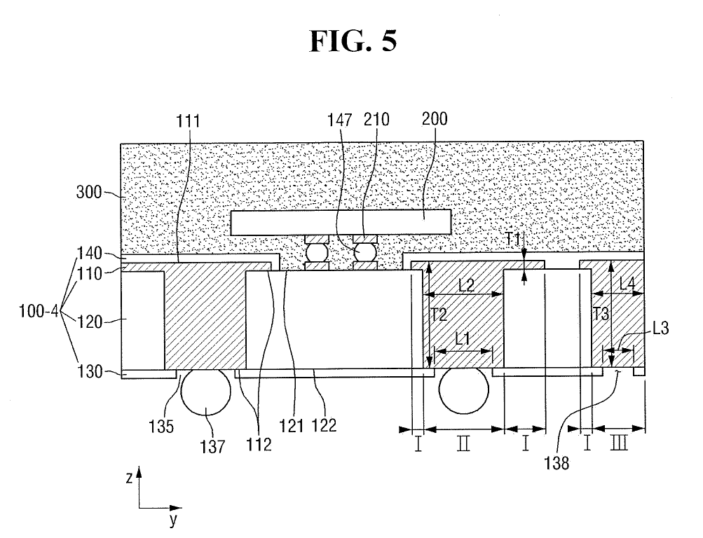

A PCB according to another embodiment will be described with reference to FIG. 5. FIG. 5 is a cross-sectional view of a semiconductor package including a printed circuit board according to the embodiment. The following description will focus on differences between the PCBs according to this embodiment and the previously described embodiments.

Referring to FIG. 5, in the PCB 100-4 according to this embodiment, a first protection layer 130 may cover only a part of the second surface 112 of the wire pattern 110 in the third region (III), unlike in the PCB 100-3 illustrated in FIG. 4. The first protection layer 130 may cover the part of the second surface 112 of the wire pattern 110 in the third region (III) such that the PCB 100-4 according to this embodiment may include a third opening 138 exposing part of the second surface 112 of the wire pattern 110 in the third region (III). The third opening 138 may be formed on the second surface 112 of the wire pattern 110 in the third region (III). A width L3 of the third opening 138 may be smaller than a width L4 of the third region (III) of the wire pattern 110.

In the PCB 100-4 according to this embodiment, a part of the second surface 112 of the wire pattern 110 in the third region (III) may be exposed through the third opening 138. Accordingly, heat of the wire pattern 110 may be emitted through the third opening 138. The heat may be emitted through the third opening 138 so that the reliability of the semiconductor device including the PCB 100-4 may be improved.

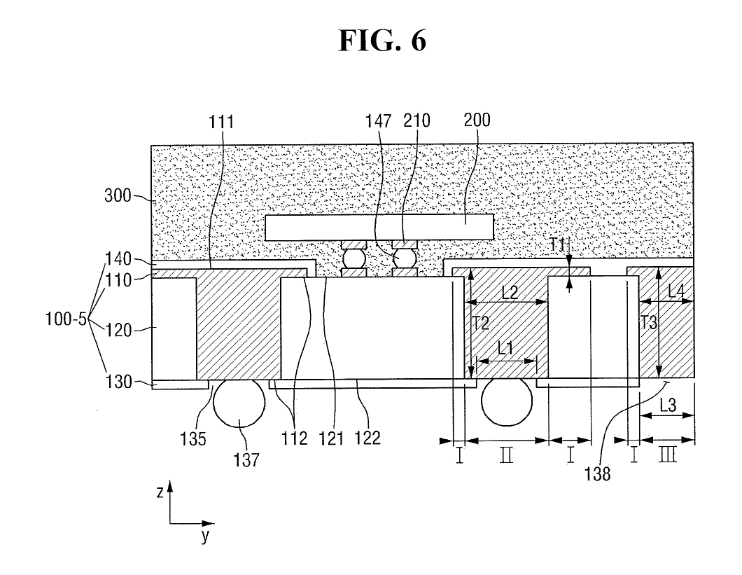

A PCB according to another embodiment will be described with reference to FIG. 6. FIG. 6 is a cross-sectional view of a semiconductor package including a printed circuit board according to the embodiment. The following description will focus on differences between the PCB according to this embodiment and the PCBs according to previously described embodiments.

Referring to FIG. 6, in the PCB 100-5 according to this embodiment, a first protection layer 130 may not cover the second surface 112 of the wire pattern 110 in the third region (III), unlike in the PCB (100-2) illustrated in FIG. 3. A third opening 138 may be formed on the second surface 112 of the wire pattern 110 in the third region (III). A width L3 of the third opening 138 may be equal to or greater than a width L4 of the third region (III) of the wire pattern 110. FIG. 6 shows that the width L4 of the third region (III) of the wire pattern 110 is equal to the width L3 of the third opening 138, as an example.

In the PCB 100-5 according to this embodiment, the second surface 112 of the wire pattern 110 in the third region (III) may be exposed through the third opening 138. Accordingly, heat of the wire pattern 110 may be emitted through the third opening 138, and the reliability of the semiconductor device including the PCB 100-5 may be improved.

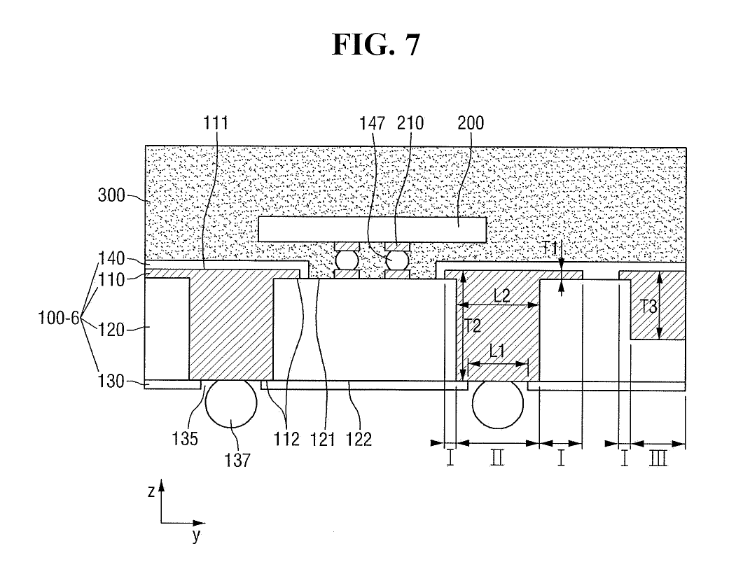

FIG. 7 is a cross-sectional view of a semiconductor package including a printed circuit board according to another embodiment. The following description will focus on differences between this PCB and the PCBs according to the previously described embodiments.

Referring to FIG. 7, in the PCB 100-6 according to this embodiment, a third thickness T3 of the third region (III) of the wire pattern 110 may be greater than a first thickness T1 and smaller than a second thickness T2, unlike in the PCB (100-2) of FIG. 3. For example, the third thickness T3 may be greater than twice the first thickness T1.

The third thickness T3 of the third region (III) of the wire pattern 110 may be smaller than the second thickness T2 of the third region (III) of the wire pattern 110. The core insulation layer 120 may be formed on the second surface 112 of the wire pattern 110 in the third region (III). The core insulation layer 120 may be formed between the second surface 112 of the wire pattern 110 in the third region (III) and the first protection layer 130.

The PCB 100-6 according to this embodiment includes the third region (III) of the wire pattern 110, which extends toward the z axis direction. Accordingly, a sufficiently wide area of the third region (III) of the wire pattern 110 may be secured. Therefore, electrical performance of a semiconductor device using the PCB 100-6 according to this embodiment may be prevented from being degraded.

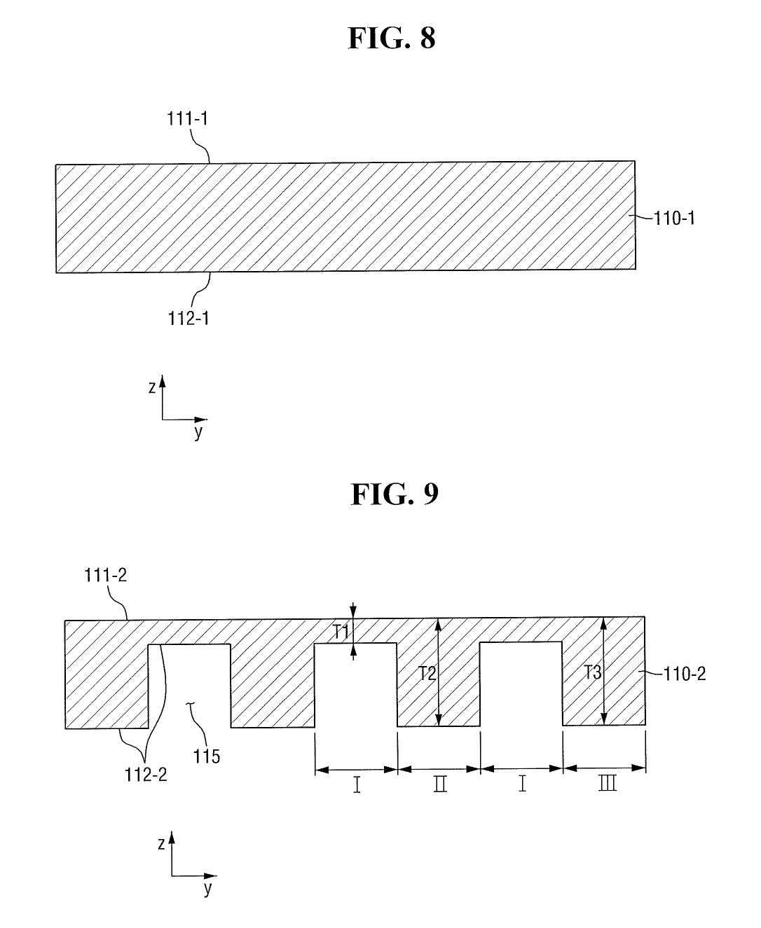

A manufacturing method of a printed circuit board according to an embodiment will be described with reference to FIGS. 8 to 13. FIGS. 8 to 12 are cross-sectional views of intermediate structures for explaining a manufacturing method of a printed circuit board according to this embodiment. FIG. 13 is a plan view of a printed circuit board according to an embodiment.

Referring first to FIG. 8, a conductive layer 110-1 having first and second surfaces 111-1 and 112-1 may be provided. The conductive layer 110-1 may include copper (Cu), as an example.

Next, referring to FIG. 9, as an example, the second surface (112-1 of FIG. 8) of the conductive layer 110-1 may be partially etched, thereby forming a conductive layer pattern 110-2 having first to third regions (I, II, and III). Part of the second surface (112-1 of FIG. 8) of the conductive layer 110-1 may be etched, forming a trench 115. For example, the trench 115 may be formed in a first region (I) of the conductive layer pattern 110-2.

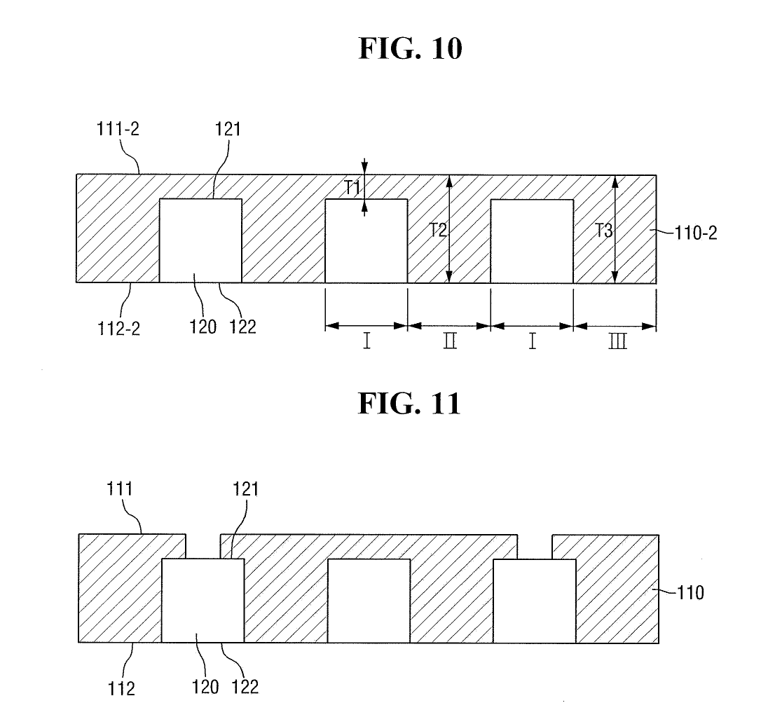

In detail, the conductive layer pattern 110-2 may have first and second surfaces 111-2 and 112-2 facing in opposite directions from each other. The first region (I) may be defined as a region of the conductive layer pattern 110-2 having a first thickness (T1), and the second region (II) may be defined as a region of the conductive layer pattern 110-2 having a second thickness (T2). A third region (III) may be defined as a region of the conductive layer pattern 110-2 having a third thickness T3. The second thickness (T2) may be greater than the first thickness (T1). The third thickness T3 may be greater than the first thickness (T1) and smaller than, or equal to, the second thickness T2. FIG. 10 shows that the second thickness T2 and the third thickness T3 are equal to each other, as an example.

As a result, the second region (II) and the third region (III) of the conductive layer pattern 110-2 may extend toward the z axis direction, compared to the first region (I) of the conductive layer pattern 110-2.

Next, referring to FIG. 10, a trench (115 of FIG. 9) of the conductive layer pattern 110-2 may be filled with an insulating material, thereby forming a core insulation layer 120. The core insulation layer 120 may be formed on the first region (I) of the conductive layer pattern 110-2, for example. The fourth surface 122 of the core insulation layer 120 and the second surface 112-2 of the conductive layer pattern 110-2 in the second region (II), and the fourth surface 122 of the core insulation layer 120 and the second surface 112-2 of the conductive layer pattern 110-2 in the third region (III), may be connected to each other. The fourth surface 122 of the core insulation layer 120, the second surface 112-2 of the conductive layer pattern 110-2 in the second region (II), and the second surface 112-2 of the conductive layer pattern 110-2 in the third region (III) may be co-planar.

Next, referring to FIG. 11, in order to form a desired circuit, the first surface (111-2 of FIG. 10) of the conductive layer pattern (110-2 of FIG. 10) is patterned, thereby forming a wire pattern 110.

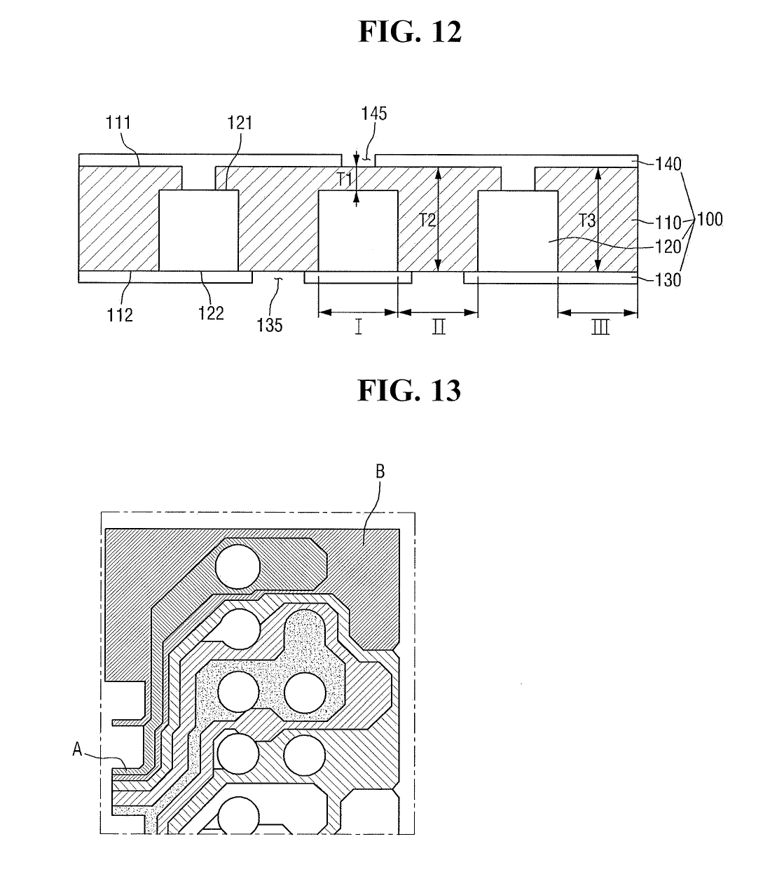

Next, referring to FIG. 12, a first protection layer 130 may be formed on the second surface 112 of the wire pattern 110 in the second and third regions (II and III) and on the fourth surface 122 of the core insulation layer 120. The first protection layer 130 may include a first opening 135. The first opening 135 may be formed on the second surface 112 of the wire pattern 110 in the second region (II). FIG. 12 shows that a first protection layer 130 covers the second surface 112 of the wire pattern 110 in the third region (III), as an example.

In addition, a second protection layer 140 may be formed on the first surface 111 of the wire pattern 110 and the third surface 121 of the core insulation layer 120. If desired, the second protection layer 140 may include a second opening 145.

The first to third regions (I, II, and III) of the wire pattern 110 of a PCB 100 will be described with reference to FIGS. 12 and 13.

As a thickness of the PCB 100 becomes greater, a patterning margin may be difficult to secure, thereby making it difficult to achieve accurate patterning. Therefore, an area on the PCB 100 where a fine circuit is formed, such as the area ‘A’ in FIG. 13, may require relatively accurate patterning. In this case, the area may correspond to the first region (I) having the first thickness T1, which is a relatively narrow area. An area ‘B’, which is a relatively wide area, may correspond to the second and third regions (II and III) having a relatively great thickness.

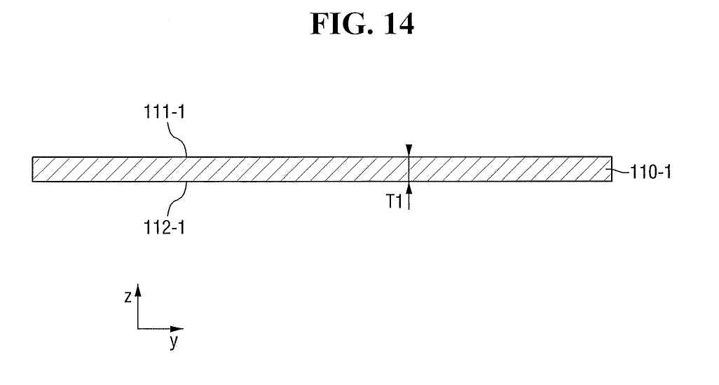

A manufacturing method of a printed circuit board according to another embodiment will be described with reference to FIG. 14. FIG. 14 is a cross-sectional view of an intermediate structure for explaining a manufacturing method of a printed circuit board according to this embodiment. However, the following description will be focus on differences between the manufacturing methods according to this embodiment and the previously described embodiment.

Referring to FIG. 14 together with FIG. 9, in the manufacturing method of the PCB according to this embodiment, in order to form a conductive layer pattern 110-2 (FIG. 9), a conductive layer 110-1 is not etched. Instead, plating may be performed on a second surface 112-1 of the conductive layer 110-1.

In detail, referring to FIG. 14, a conductive layer 110-1 having first and second surfaces 111-1 and 112-1 may be provided. For example, the conductive layer 110-1 may have a first thickness T1.

Next, referring to FIG. 9, for example, the second surface (112-1 of FIG. 14) of the conductive layer 110-1 may be partially plated, thereby forming a conductive layer pattern 110-2 having first to third regions (I, II, and III). For example, the second region (II) and the third region (III) may be additionally plated, and may have a relatively greater thickness.

By way of summation and review, a semiconductor package may be fabricated using semiconductor chips, a printed circuit board (PCB) on which semiconductor chips are mounted, and a sealing member for sealing the semiconductor chips. A typical two-layer PCB used in fabricating a semiconductor package may be expensive to manufacture because the PCB forming process may involve forming vias. Specifically, in manufacturing a PCB including a plurality of wire patterns on two sides, a high cost may be incurred in forming vias.

In order to reduce the cost of a semiconductor package, a method of using a printed circuit board including a wire pattern not requiring fabrication of vias may be considered. However, compared to a printed circuit board including a multiple-layer wire pattern, the printed circuit board including a wire pattern may have a narrow area for a circuit pattern. Therefore, a printed circuit board including a wire pattern may also have a narrow area for voltage and ground circuit patterns. Accordingly, the electrical performance of a semiconductor device using a printed circuit board including such a wire pattern may be degraded.

Embodiments disclosed herein may provide a printed circuit board including a wire pattern in which degradation of the electrical performance thereof may be prevented or reduced by sufficiently securing an area for voltage and ground circuit patterns.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A printed circuit board (PCB), comprising:
a wire pattern having first and second surfaces facing in opposite directions from each other, the wire pattern including a first region having a first thickness and a second region having a second thickness greater than the first thickness;
a core insulation layer on the second surface in the first region, the core insulation layer having a third surface adjacent to the second surface in the first region and a fourth surface facing in an opposite direction from the third surface, the fourth surface being connected to the second surface; and
a first protection layer covering a portion of the fourth surface of the core insulation layer and a portion of the second surface in the second region.

2. The PCB as claimed in claim 1, wherein:
the first protection layer includes an opening exposing another portion of the second surface in the second region, and
a width of the opening is smaller than a width of the second region.

3. The PCB as claimed in claim 2, further comprising a first external connection terminal on the second surface in the second region, the first external connection terminal extending through the opening.

4. The PCB as claimed in claim 3, further comprising a second external connection terminal on the first surface in the first region.

5. The PCB as claimed in claim 1, further comprising a second protection layer on the first surface of the wire pattern.

6. The PCB as claimed in claim 1, wherein the wire pattern further includes a third region having a third thickness greater than the first thickness and not greater than the second thickness.

7. The PCB as claimed in claim 6, wherein the third thickness is two or more times greater than the first thickness.

8. The PCB as claimed in claim 6, wherein the first protection layer covers the second surface in the third region.

9. The PCB as claimed in claim 1, wherein the second region is a region to which an external voltage is applied or a region that is grounded.

10. The PCB as claimed in claim 1, wherein the first region of the wire pattern is not on the fourth surface of the core insulation layer.

11. A printed circuit board (PCB), comprising:
a wire pattern having first and second surfaces facing in opposite directions from each other, the wire pattern including a first region having a first thickness, a second region having a second thickness greater than the first thickness, and third region having a third thickness greater than the first thickness and not greater than the second thickness;
a core insulation layer on the second surface of the wire pattern in the first region, the core insulation layer having a third surface adjacent to the second surface of the wire pattern in the first region and a fourth surface facing in an opposite direction from the third surface, the fourth surface being connected to the second surface of the wire pattern; and
a first external connection terminal formed on the second surface of the wire pattern in the second region but not in the third region.

12. The PCB as claimed in claim 11, further comprising a first protection layer covering at least a portion of the second surface of the wire pattern in the third region.

13. The PCB as claimed in claim 12, further comprising a second protection layer on the first surface of the wire pattern.

14. The PCB as claimed in claim 11, further comprising a first protection layer covering a portion of the fourth surface of the core insulation layer and a portion of the second surface of the wire pattern in the second region, the first protection layer including an opening exposing another portion of the second surface of the wire pattern in the second region, wherein:
a width of the opening is smaller than that of the second region, and
the first external connection terminal is formed on the second surface of the wire pattern in second region through the opening.

15. The PCB as claimed in claim 11, wherein the core insulation layer is also on the second surface of the wire pattern in the third region.

16. A semiconductor package, comprising:
a semiconductor device;
a printed circuit board (PCB) on which the semiconductor device is mounted; and
a sealing member sealing the semiconductor device,
the printed circuit board including:
a wire pattern having first and second surfaces facing in opposite directions from each other, the wire pattern including a first region having a first thickness and a second region having a second thickness greater than the first thickness, the second surface in the second region being stepped from the second surface in the first region,
a core insulation layer on the second surface in the first region, the core insulation layer having a third surface contacting the second surface in the first region and a fourth surface facing in an opposite direction from the third surface, the fourth surface being connected to and co-planar with the second surface,
a first protection layer covering a portion of the fourth surface,
a first external connection terminal on the second surface in the second region, and
a second external connection terminal on the first surface, the semiconductor device being mounted on the PCB using the second external connection terminal.

17. The semiconductor package as claimed in claim 16, wherein:
the first protection layer covers a portion of the second surface in the second region and includes an opening exposing another portion of the second surface in the second region, a width of the opening being smaller than a width of the second region, and the first external connection terminal extending through the opening.

18. The semiconductor package as claimed in claim 16, wherein the wire pattern further includes a third region having a third thickness greater than the first thickness and not greater than the second thickness.

19. The semiconductor package as claimed in claim 18, wherein the first protection layer covers at least a portion of the second surface in the third region.

20. The semiconductor package as claimed in claim 18, wherein:
the third thickness of the second surface is less than the second thickness of the second surface, and
the core insulation layer is on the second surface in the third region.
